(19) United States
(12) Patent Application Publication
(10) Pub. No.: US 2007/0292672 A1
(43) Pub. Date: Dec. 20, 2007

(54) Coated inserts

(75) Inventors: Bjorn Ljungberg, Enskede (SE); Leif Akesson, Alvsjo (SE); Ibrahim Sadik, Kista (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB

(21) Appl. No.: 11/802,570

(22) Filed: May 23, 2007

(30) Foreign Application Priority Data
Jun. 15, 2006 (SE) 0601313-0

(51) Int. Cl. B32B 7/02; C23C 16/00

(52) U.S. Cl. 428/216; 427/249.19

(57) ABSTRACT

Coated cemented carbide milling inserts, particularly useful for rough and semifinishing milling of grey cast iron, highly alloyed grey cast iron, compacted graphite iron (CGI) with or without cast skin under dry conditions are described.

The inserts are characterised by a WC-Co cemented carbide with a low content of cubic carbides and a W-alloyed binder phase and a coating including an inner layer of TiCₓN_{y} with columnar grains followed by a wet blasted layer of α-Al₂O₃.on the rake face and colored top layer on the clearance side.

The invention also relates to methods of making and using cutting tool inserts according to the above.

The present invention relates to coated cemented carbide milling inserts, particularly useful for rough and semifinishing milling of grey cast iron, highly alloyed grey cast iron and compacted graphite iron (cgi) with or without cast skin, under dry conditions.

### BACKGROUND OF THE INVENTION

When cemented carbide cutting tool inserts are used in the machining of cast irons, the cutting edge is worn according to different wear mechanisms such as chemical and abrasive wear. Additionally, a milling cutting edge is also most often subjected to the so-called comb crack formation. These cracks develop perpendicularly to the cutting edge and are a result of the cycling mechanical and heat load. When the comb cracks have propagated deep enough into the carbide body, the cutting edge starts to chip and fracture.

A typical characteristic of a cast iron component is its hard surface zone which structure considerably deviates from its bulk structure. The surface zone generally contains hard inclusion and sand from the mold. This makes cutting of cast iron very demanding. A cutting tool insert should also be able to cope with broad range of cutting conditions, such as various cutting speeds, depths of cut and cutting feed rates as well as manage external factors such as vibrations of the work piece.

All these factors require a plurality of properties of the cutting tool insert. Commercial cemented carbide tool inserts for milling of cast irons have usually been optimized with respect to one or two of mentioned wear types.

U.S. Pat. No. 5,912,051 discloses a coated cutting insert particularly useful for dry milling of grey cast iron.

In U.S. Pat. No. 6,062,776 is disclosed a coated cemented carbide cutting tool particularly designed for the wet and dry milling of workpieces of low and medium alloyed steels or stainless steels, with or without abrasive surface zones, in machining operations requiring a high degree of toughness of the carbide cutting edge. The external cutting conditions are characterized by complex shapes of the workpiece, vibrations, chip hammering, recutting of the chips etc.

In U.S. Pat. No. 6,177,178 is disclosed a coated cemented carbide cutting tool particularly designed for the wet and dry milling of low and medium alloyed steels.

WO 01/16388 discloses a coated insert particularly useful for milling in low and medium alloyed steels with or without abrasive surface zones during dry or wet conditions at high cutting speed, and milling hardened steels at high cutting speed.

U.S. Pat. No. 6,638,609 discloses coated milling inserts particularly useful for milling of grey cast iron with or without cast skin under wet conditions at low and moderate cutting speeds and milling of nodular cast iron and compacted graphite iron with or without cast skin under wet conditions at moderate cutting speeds.

US Patent Application 2006/0115683 discloses coated milling inserts particularly useful for milling of grey cast iron with or without cast skin under dry conditions at preferably rather high cutting speeds and milling of nodular cast iron and compacted graphite iron with or without cast skin under dry conditions at rather high cutting speeds. The inserts are characterised by a WC-Co cemented carbide with a low content of cubic carbides and a highly W-alloyed binder phase and a coating including an inner layer of TiCₓN_{y} with columnar grains followed by a wet blasted layer of α-Al₂O₃.

Cast irons are also very demanding when it comes to wear resistance due to non-metallic inclusions and/or cast skin, and therefore CVD-coated inserts have been commonly used, e.g. according to U.S. Pat. No. 5,912,051, U.S. Pat. No. 5,942,318, U.S. Pat. No. 6,767,583.

WO 2006/043421 discloses cemented carbides which include WC having an average particle diameter of 0.3 μm or less as a hard phase and 5.5 to 15 wt-% of at least one iron group metal element as a binder phase, and comprise, in addition to the above hard phase and binding phase, 0.005 to 0.06 wt-% of Ti, Cr in a weight ratio relative to the binder phase of 0.04 to 0.2, and the balanced amount of inevitable impurities. Especially, the cemented carbides contain no Ta.

### OBJECTS AND SUMMARY OF THE INVENTION

It is the object of present invention to provide coated cemented carbide cutting tool inserts with significantly improved cutting performance over corresponding prior art inserts, particularly useful for rough milling under dry conditions of grey cast iron, highly alloyed grey cast iron, and compacted graphite iron, preferably at higher cutting speeds.

In one aspect of the invention, there is provided a cutting tool insert comprising a cemented carbide body and a coating, said cemented carbide body having an edge radius of from about 25 to about 50 μm, comprising WC, from about 7.3 to about 7.9 wt-% Co and from about 1.0 to about 2.0 wt-% cubic carbides of the metals Ti, Ta and Nb, a CW-ratio of from about 0.85 to about 0.94, a coercivity, Hc, of from about 13.8 to about 15.7 kA/m, said coating comprising a first, innermost layer of TiCₓN_{y}O_{z} with x+y+z=1, y>x and z less than about 0.2 and a total thickness of from about 0.1 to about 1.5 μm, a second layer of TiCₓN_{y} with x+y=1, x more than about 0.3 and y more than about 0.3, with a thickness of from about 4.5 to about 9.5 μm, with columnar grains, a third layer of TiCₓN_{y}O_{z} with x+y+z=1, x more than about 0.3 and z more than about 0.3, y equal to or greater than 0 and less than about 0.2, with a thickness of from about 0.3 to about 1.5 μm, a fourth layer of smooth α-Al₂O₃ with a thickness of from about 9 to about 15 μm, and a from about 0.1 to about 2 μm thick colored top layer on the clearance side.

In another aspect of the invention, there is provided a method of making a milling cutting tool insert comprising a cemented carbide body and a coating comprising providing a cemented carbide body comprising WC, from about 7.3 to about 7.9 wt-% Co and from about 1.0 to about 2.0 wt-% cubic carbides of the metals Ti, Ta and Nb and a W-alloyed binder phase with a CW-ratio of from about 0.85 to about 0.94, a coercivity, Hc, of from about 13.8 to about 15.7 kA/m, wet blasting the inserts to from about 25 to about 50 μm edge rounding, depositing by a CVD-method a first, innermost layer of TiCₓN_{y}O_{z} with x+y+z=1, y>x and z less than about 0.2 and a thickness of from about 0.1 to about 1.5 μm, depositing by an MTCVD-technique, a second layer of TiCₓN_{y} with x+y=1, x more than about 0.3 and y more than about 0.3 with a thickness of from about 4.5 to about 9.5 μm having a columnar grain structure, wherein the MTCVD-technique uses acetonitrile as a source of carbon and nitrogen for forming a layer in a temperature range of from about 700 to about 900° C., depositing by a CVD-method a third layer of TiCₓN_{y}O_{z} with x+y+z=1, x more than about 0.3 and z more than about 0.3, y equal to or greater than zero and less than about 0.2, with a thickness of from about 0.3 to about 1.5 μm, depositing a fourth layer of α-Al₂O₃ with a thickness of from about 9 to about 15 μm using known CVD-methods and depositing a from about 0.1 to about 2 μm thick colored top layer on the clearance side, using CVD or PVD-technique and wet blasting the Al₂O₃-layer on the rake face and along the using a slurry comprising Al₂O₃ grits in water.

A still further aspect of the invention provides the use of a cutting tool insert as set forth above for dry milling of cast irons at a cutting speed of from about 150 to about 375 m/min and a feed of from about 0.1 to about 0.35 mm/tooth depending on cutting speed and insert geometry.

### DETAILED DESCRIPTION OF THE PREFERRED EMBODIMENTS

It has now surprisingly been found that improved properties of milling cutting tool inserts can be obtained with respect to the different wear types prevailing at the above mentioned cutting operations if the inserts comprise: a cemented carbide body with a W-alloyed binder phase and with a well balanced chemical composition and a certain grain size of the WC, a columnar TiCₓN_{y} -layer and a post treated α-Al₂O₃ top layer.

According to the present invention, coated cutting tool inserts are provided comprising a cemented carbide body with a composition of from about 7.3 to about 7.9 wt-% Co, preferably from about 7.5 to about 7.7 wt-% Co, from about 1.0 to about 2.0 wt-%, preferably from about 1.3 to about 1.7 wt-%, cubic carbides of the metals Ta, Nb and Ti and balance WC, preferably 90.6-91.2 wt-% WC. The Ti-content is preferably on the level of technical impurity or less, down to 0. The coercivity, Hc, should have a value in the range from about 13.8 to about 15.7 kA/m, preferably within from about 14.2 to about 15.2 kA/m.

The cobalt binder phase is alloyed with W. The content of W in the binder phase is expressed as the

CW-ratio=magnetic-% Co/wt-% Co

where magnetic-% Co is the weight percentage of magnetic Co and wt-% Co is the weight percentage of Co in the cemented carbide.

The CW-value is a function of the W content in the Co binder phase. A CW-value of from about 0.75 to about 0.8 corresponds to a very high W-content in the binder phase whereas a CW-ratio of 1 corresponds in principle to no W-alloying.

According to the present invention improved cutting performance is achieved if:

A) the cemented carbide body has a cobalt binder alloyed with W corresponding to a CW-ratio of from about 0.85 to about 0.94, preferably of from about 0.88 to about 0.92 and

B) the inserts have an from about 25 to about 50 μm edge rounding before coating.

C) the coating comprises

a first, innermost layer of TiCₓN_{y}O_{z} with x+y+z=1, y>x and z less than about 0.2, preferably y more than about 0.8 and z=0 and a thickness of from about 0.1 to about 1.5 μm, preferably more than about 0.4 μm.

a second layer of TiCₓN_{y} with x+y=1, x more than about 0.3 and y more than about 0.3, with a thickness of from about 4.5 to about 9.5 μm, preferably from about 5 to about 7.5 μm, with columnar grains.

a third layer of TiCₓN_{y}O_{z} with x+y+z=1, x more than about 0.3 and z more than about 0.3, y equal to or greater than 0 and less than about 0.2, with a thickness of from about 0.3 to about 1.5 μm.

a fourth layer of a smooth α-Al₂O₃ with a thickness of from about 9 to about 15 μm, preferably from about 10 to about 12 μm and a surface roughness in the cutting area zone of Ra<0.4 μm over a length of 10 μm.

The ratio of layer thicknesses of the fourth layer Al₂O₃ and the second layer of TiCₓN_{y} is preferably from about 1.3 to about 2.4.

a from about 0.1 to about 2 μm thick colored top layer, preferably TiN or ZrN, on the clearance side.

The present invention also relates to a method of making coated cutting tool inserts consisting of a cemented carbide body with a composition of from about 7.3 to about 7.9 wt-% Co, preferably from about 7.5 to about 7.7 wt-% Co, from about 1.0 to about 2.0 wt-%, preferably from about 1.3 to about 1.7 wt-%, cubic carbides of the metals Ta, Nb and Ti and balance WC, preferably from about 90.6 to about 91.2 wt-% WC. The Ti-content is preferably on the level of technical impurity or less, down to 0. The manufacturing conditions are chosen to obtain an as sintered structure with the coercivity, Hc, of from about 13.8 to about 15.7 kA/m, preferably from about 14.2 to about 15.2 kA/m and a cobalt binder phase alloyed with W corresponding to a CW-ratio of from about 0.85 to about 0.94, preferably from about 0.88 to about 0.92 defined as above. After wet blasting the inserts to from about 25 to about 50 μm edge rounding, a coating comprising the following layers is deposited:

a first, innermost layer of TiCₓN_{y}O_{z} with x+y+z=1, y more than about x and z less than about 0.2, preferably y more than about 0.8 and z=0 and a total thickness from about 0.1 to about 1.5 μm, preferably more than about 0.4 μm, using known CVD-methods,

a second layer of TiCₓN_{y} with x+y=1, x more than about 0.3 and y more than about 0.3, preferably x more than about 0.5, with a thickness of from about 4.5 to about 9.5 μm, preferably from about 5 to about 7.5 μm, with columnar grains using the MTCVD-technique with acetonitrile as the carbon and nitrogen source for forming the layer in the temperature range of from about 700 to about 900° C. The exact conditions, however, depend to a certain extent on the design of the equipment used,

a third layer of TiCₓN_{y}O_{z} with x+y+z=1, x more than about 0.3 and z more than about 0.3, y is equal to or greater than zero and less than about 0.2, with a thickness of from about 0.3 to about 1.5 μm, produced by CVD using the reaction mixtures TiCl₄, CO, H₂ or TiCl₄, CO, H₂, N₂,

a fourth layer of a smooth α-Al₂O₃, with a thickness of from about 9 to about 15 μm, preferably from about 10 to about 12 μm using known CVD-methods.

The ratio of layer thicknesses of the fourth layer Al₂O₃ and the second layer of TiCₓN_{y} is preferably from about 1.3 to about 2.4.

a from about 0.1 to about 2 μm thick colored top layer, preferably TiN or ZrN, using CVD or PVD-technique.

Finally, the Al₂O₃-layer on the rake face and along the cutting edge line is subjected to an intense wet blasting operation to obtain a smooth surface finish, preferably with a surface roughness in the cutting area zone of Ra<0.4 μm over a length of 10 μm using a slurry comprising Al₂O₃ grits and water. Alternatively, this wet-blasting step may be performed prior to the deposition of the colored top layer on the clearance faces.

The invention also relates to the use of a cutting tool insert as described above for the dry milling of cast irons such as grey cast iron, highly alloyed grey cast iron or compacted graphite iron at a cutting speed of from about 150 to about 375 m/min and a feed of from about 0.1 to about 0.35 mm/tooth depending on cutting speed and insert geometry.

The invention is additionally illustrated in connection with the following examples, which are to be considered as illustrative of the present invention. It should be understood, however, that the invention is not limited to the specific details of the examples.

### EXAMPLE 1

### (Invention)

Cemented carbide milling blanks were pressed in styles R245-12T3M-KM, R290-12T308M-KM and SPKN1204 EDR from powder with the composition 7.6 wt-% Co, 1.25 wt-% TaC, 0.30 wt-% NbC and balance WC and sintered with normal technique at 1410° C. giving as-sintered inserts with an Hc value of 14.7 kA/m and a magnetic Co-content of 6.85 wt-% corresponding to a CW-ratio of 0.90. The inserts were edge rounded using a wet blasting method to a radius of 35 μm and then coated with a first 0.5 μm thick TiCₓN_{y}-layer with a high nitrogen content corresponding to a y-value of about 0.95, followed by a second 6 μm thick TiCₓN_{y}-layer, with an x-value of about 0.55 and with a columnar grain structure using MTCVD-technique (temperature 850-885° C. and CH₃CN as the carbon/nitrogen source). In subsequent steps during the same coating cycle, a third 1 μm thick Ti(C,O)-layer was deposited followed by a fourth 11 μm thick layer of α-Al₂O₃ and a 1 μm thick top layer of TiN.

The inserts were wet blasted on the rake face with alumina grit in order to remove the top TiN-layer and to produce a smooth surface finish of the exposed Al₂O₃-layer of Ra=0.2 μm over a length of 10 μm.

### EXAMPLE 2

### (Prior Art)

Cemented carbide milling inserts according to table 1 with the same insert styles as in Example 1 were produced according to known technique.

TABLE 1

| | Substrate | | | | | | Coating |
|---|---|---|---|---|---|---|---|
| | composition, wt-% | | | | Hc, | CW- | thickness, |
| Variant | Co | TaC | NbC | WC | kA/m | ratio | μm and type |
| Ref A | 6.0 | — | — | Rest | 16.1 | 0.94 | 5.5 TiCN, 4.0 |
| | | | | | | | α-Al₂O₃ |
| Ref B | 7.6 | 1.25 | 0.27 | Rest | 14.8 | 0.91 | 7.1 TiCN, 7.0 |
| | | | | | | | α-Al₂O₃ |

### EXAMPLE 3

Inserts from Example 1 according to the present invention were tested in a face milling of cylinder heads in highly alloyed grey cast iron.

Tool: R245-12T3M-KM

Number of inserts in the cutter: 24 pcs

Criterion: Surface finish and work piece frittering.

Reference: R245-12T3M-KM, prior art Ref A from Example 2

Cutting data

Cutting speed: Vc=350 m/min

Feed rate: Fz=0.15 mm per tooth

Depth of cut: Ap=0.5 mm

Dry conditions

The tool life of Ref A was 174 cylinder heads and 215 cylinder heads for inserts according to the invention was measured.

Results: Increased tool life by 23% and improved surface finish with the inserts according to the invention.

### EXAMPLE 4

Inserts from Example 1 according to the invention were tested in a face milling of a central block in highly alloyed grey cast iron.

Tool: R245-12T3M-KM

Number of inserts in the cutter: 10 pcs

Criteria: Surface finish and work piece frittering.

Reference R245-12T3M-KM, prior art Ref A from Example 2.

Cutting data

Cutting speed: Vc=251 m/min

Feed rate: Fz=0.24 mm per tooth

Depth of cut: Ap=2-3 mm

Dry conditions

The tool life as an average of two tests was 50 minutes for Ref A and 80 minutes for inserts according to the invention.

### EXAMPLE 5

Inserts from Example 1 according to the present invention were tested in face milling of a Hub swivel for a generator engine made of grey cast iron

Tool: SPKN1204 EDR

Number of inserts in the cutter: 8 pcs

Criteria: Surface finish and work piece frittering.

Reference SPKN1204 EDR, prior art Ref B from Example 2.

Cutting data

Cutting speed: Vc=350 m/min

Feed rate: Fz=0.19 mm per tooth

Depth of cut: Ap=3-4 mm

Dry conditions

The tool life of Ref B and of inserts according to the invention was 38 and 56 minutes, respectively.

### EXAMPLE 6

Inserts from Example 1 according to the present invention were tested in a face milling of cylinder heads in compacted graphite iron (CGI).

Tool: R290-12T308M-KM

Number of inserts in the cutter: 6 pcs

Criterion: Surface finish and work piece frittering.

Reference: R290-12T308M-KM, prior art Ref A from Example 2.

Cutting data

Cutting speed: Vc=300 m/min

Feed rate: Fz=0.15 mm per tooth

Depth of cut: Ap=3.0 mm

Dry conditions

The tool life of Ref A and the inserts according to the invention was 60 cylinder heads and 85 cylinder heads, respectively.

From Examples 3-6 it is evident that the insert according to the invention shows much better cutting performance than inserts according to prior art. The main advantage is a slower growth of the flank and crater wear, due to a well balanced composition of the cemented carbide body together with a very big total coating thickness.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. A cutting tool insert comprising a cemented carbide body and a coating said cemented carbide body having an edge radius of from about 25 to about 50 μm, comprising WC, from about 7.3 to about 7.9 wt-% Co and from about 1.0 to about 2.0 wt-% cubic carbides of the metals Ti, Ta and Nb, a CW-ratio of from about 0.85 to about 0.94, a coercivity, Hc, of from about 13.8 to about 15.7 kA/m and in that said coating comprising
a first, innermost layer of TiCₓN_{y}O_{z} with x+y+z=1, y>x and z less than about 0.2 and a total thickness of from about 0.1 to about 1.5 μm,
a second layer of TiCₓN_{y} with x+y=1, x more than about 0.3 and y more than about 0.3, with a thickness of from about 4.5 to about 9.5 μm, with columnar grains,
a third layer of TiCₓN_{y}O_{z} with x+y+z=1, x more than about 0.3 and z more than about 0.3, y is equal to or greater than zero and less than about 0.2, with a thickness of from about 0.3 to about 1.5 μm,
a fourth layer of a smooth α-Al₂O₃ with a thickness of from about 9 to about 15 μm, and
a from about 0.1 to about 2 μm thick colored top layer on the clearance side.

2. An insert of claim 1 wherein said cemented carbide body has a Ti-content on the level of technical impurity or less.

3. An insert of claim 1 in which the cemented carbide body contains from about 1.3 to about 1.7 wt-% carbides of Ta and Nb.

4. An insert of claim 1 wherein said fourth layer of smooth α-Al₂O₃ has a surface roughness in the cutting area zone of Ra<0.4 μm over a length of 10 μm.

5. An insert of claim 1 wherein the said colored top layer on the clearance side comprises TiN or ZrN.

6. An insert of claim 1 wherein said cemented carbide body comprises from about 7.5 to about 7.7 wt-% Co, from about 1.3 to about 1.7 wt-% cubic carbides of the metals Ta, Nb and Ti, from about 90.6 to about 91.2 wt-% WC, a coercivity of from 14.2 to about 15.2 kA/m and a CW-ratio of from about 0.88 to about 0.92.

7. An insert of claim 1 wherein in said coating, in the first, innermost layer, y is greater than about 0.8 and a thickness of greater than about 0.4 μm; said second layer has a thickness of from about 5 to about 7.5 μm; said fourth layer has a thickness of from about 10 to about 12 μm; the ratio of layer thicknesses of the fourth layer and the second layer is from about 1.3 to about 2.4; and said colored top layer comprises TiN or ZrN.

8. Method of making a milling cutting tool insert comprising a cemented carbide body and a coating comprising:
providing a cemented carbide body comprising WC, from about 7.3 to about 7.9 wt-% Co and from about 1.0 to about 2.0 wt-% cubic carbides of the metals Ti, Ta and Nb and a W-alloyed binder phase with a CW-ratio of from about 0.85 to about 0.94, a coercivity, Hc, of from about 13.8 to about 15.7 kA/m,
wet blasting the inserts to from about 25 to about 50 μm edge rounding,
depositing by a CVD-method a first, innermost layer of TiCₓN_{y}O_{z} with x+y+z=1, y>x and z less than about 0.2 and a thickness of from about 0.1 to about 1.5 μm,
depositing by an MTCVD-technique, a second layer of TiCₓN_{y} with x+y=1, x more than about 0.3 and y more than about 0.3 with a thickness of from about 4.5 to about 9.5 μm having a columnar grain structure, wherein the MTCVD-technique uses acetonitrile as a source of carbon and nitrogen for forming a layer in a temperature range of from about 700 to about 900° C.,
depositing by a CVD-method a third layer of TiCₓN_{y}O_{z} with x+y+z=1, x more than about 0.3 and z more than about 0.3, y is equal to or greater than zero and less than about 0.2, with a thickness of from about 0.3 to about 1.5 μm,
depositing a fourth layer of α-Al₂O₃ with a thickness of from about 9 to about 15 μm using known CVD-methods and
depositing a from about 0.1 to about 2 μm thick colored top layer on the clearance side, using CVD or PVD-technique and
wet blasting the Al₂O₃-layer on the rake face and along the using a slurry comprising Al₂O₃ grits in water.

9. The method of claim 8 wherein the cemented carbide body has a Ti-content on the level of technical impurity or less.

10. The method of claim 8 wherein said cemented carbide body contains from about 1.3 to about 1.7 wt-% carbides of Ta and Nb.

11. The method of claim 8 wherein said fourth layer of smooth α-Al₂O₃ has a surface roughness in the cutting area zone of Ra<0.4 μm over a length of 10 μm.

12. The method of claim 8 wherein the said colored top layer on the clearance side comprises TiN or ZrN.

13. The method of claim 8 wherein said cemented carbide body comprises from about 7.5 to about 7.7 wt-% Co, from about 1.3 to about 1.7 wt-% cubic carbides of the metals Ta, Nb and Ti, from about 90.6 to about 91.2 wt-% WC, a coercivity of from 14.2 to about 15.2 kA/m and a CW-ratio of from about 0.88 to about 0.92.

14. The method of claim 8 wherein in said coating, in the first, innermost layer, y is greater than about 0.8 and the layer has a thickness of greater than about 0.4 μm; said second layer has a thickness of from about 5 to about 7.5 μm; said fourth layer has a thickness of from about 10 to about 12 μm; the ratio of layer thicknesses of the fourth layer and the second layer is from about 1.3 to about 2.4; and said colored top layer comprises TiN or ZrN.

15. Use of a cutting tool insert according to claim 1 for dry milling of cast irons at a cutting speed of 150-375 m/min and a feed of from about 0.1 to about 0.35 mm/tooth depending on cutting speed and insert geometry.
